(19) United States
(12) Patent Application Publication
(10) Pub. No.: US 2010/0176399 A1
(43) Pub. Date: Jul. 15, 2010

(54) BACK-CHANNEL-ETCH TYPE THIN-FILM TRANSISTOR, SEMICONDUCTOR DEVICE AND MANUFACTURING METHODS THEREOF

(75) Inventor: Toru TAKEGUCHI, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/684,338

(22) Filed: Jan. 8, 2010

(30) Foreign Application Priority Data
Jan. 14, 2009 (JP) 2009-005600

(51) Int. Cl. H01L 29/786; H01L 21/20; H01L 21/336

(52) U.S. Cl. 257/57; 438/479; 257/E29.273; 257/E21.09; 257/E21.414

(57) ABSTRACT

A back-channel-etch type TFT includes a gate electrode, an SiN film that is formed on the gate electrode, and an SiO film that is formed and patterned on the SiN film. The TFT further includes an polycrystalline semiconductor film that is formed and patterned on the SiO film in contact with the SiO film in such a way that all pattern ends of the polycrystalline semiconductor film are located in close proximity to pattern ends of the SiO film.

### INCORPORATION BY REFERENCE

This application is based upon and claims the benefit of priority from Japanese patent application No. 2009-005600, filed on Jan. 14, 2009, the disclosure of which is incorporated herein in its entirety by reference.

### BACKGROUND OF THE INVENTION

1. Field of the Invention

The present invention relates to a back-channel-etch type thin-film transistor, a semiconductor device and manufacturing methods thereof.

2. Description of Related Art

A liquid crystal display (LCD), which is one of hitherto-used general low-profile panels, is widely used as a monitor of a personal computer, a monitor of a portable information terminal device and so on for its merits such as low power consumption, small size and lightweight. Further, the LCD has recently become widely used in TV applications in place of a cathode ray tube. Furthermore, an electroluminescence (EL) display that has overcome problems such as limitations on viewing angle and contrast which is a controversial issue in the LCD and difficulty in following a high-speed response for video compatibility is becoming widely used as a device for a next generation low-profile panel. The EL display in which a luminous body such as an EL device is used in a pixel display unit has features that are not found in the LCD, such as self-luminous nature, wide viewing angle, high contrast and high-speed response.

For a thin-film transistor (which is referred to hereinafter as a TFT) that is used in such a display, an MIS structure using a semiconductor film is frequently used. There are several types of TFTs such as an inversely staggered type and a top gate type, and there are also several types of semiconductor films such as an amorphous semiconductor film and a polycrystalline semiconductor film. They are appropriately selected depending on the application or performance of the display. Particularly, in the case of using a TFT that is fabricated by a semiconductor film having crystallinity with a large mobility, a driving circuit can be formed on a substrate, thus offering an advantage of reducing the number of external ICs using expensive single-crystal semiconductor.

As a method of fabricating a semiconductor film having crystallinity, a method is known that forms an amorphous semiconductor film and then polycrystallizes the semiconductor film by applying laser light. With regard to a TFT using a polycrystallized semiconductor film, a so-called back-channel-etch type TFT structure is disclosed in Japanese Unexamined Patent Application Publication No. 5-63196, for example. Specifically, a gate insulating film made of an SiN film or an SiO film is formed on a gate electrode. Further, a polycrystalline silicon film and an amorphous silicon film are formed in a stacked manner from the side in contact with the gate insulating film. The polycrystalline silicon film is formed by applying excimer laser to the amorphous silicon film.

Further, a so-called etching stopper type TFT structure is disclosed in Japanese Unexamined Patent Application Publication No. 2007-5508. Specifically, a gate insulating film in which an SiN film and an SiO film are stacked is formed on a gate electrode from the side in contact with the gate electrode. Then, a polycrystalline silicon film and an amorphous silicon film are formed in lamination from the side in contact with the gate insulating film, and further a channel protective film is formed thereon. The polycrystalline silicon film is formed by forming a buffer film and a photothermal conversion film on the amorphous silicon film and then applying semiconductor laser light thereto.

However, as disclosed in Japanese Unexamined Patent Application Publication Nos. 5-63196 and 2000-2892, in the case of using the SiN film as the gate insulating film in contact with the channel, a layer in which amorphous substance and crystalline substance are mixed is formed on the interface between the silicon film serving as the channel and the gate insulating film. Specifically, a polycrystalline silicon film 3 and an amorphous silicon film 4 are stacked on an SiN film 1 as shown in FIG. 4. An amorphous and polycrystalline mixed layer 2 is formed between the SiN film 1 and the polycrystalline silicon film 3. This is because thermal damage extends into the SiN film 1 during laser application and N in the SiN film 1 is implanted into the silicon film.

It is considered that fixed charges are generated in the amorphous and polycrystalline mixed layer 2. Therefore, if laser is applied with an irradiation energy density that crystallizes the silicon film to the interface with the gate insulating film, a problem arises that a threshold voltage is shifted. Specifically, the threshold voltage is shifted to the minus side under the influence of the fixed charges as shown in FIG. 5. FIG. 5 is a graph showing an example of TFT characteristics (linear region) in the case of using the SiN film as the gate insulating film. In FIG. 5, the horizontal axis indicates a gate voltage Vg(V), and the vertical axis indicates a drain current Id(A).

In order to reduce the thermal damage to the gate insulating film, it is necessary to set a low energy density during laser irradiation. However, in this case, it is unable to sufficiently crystallize the silicon film, which causes increase in S value and degradation of mobility. Further, if the TFT is operated by applying an external voltage, a problem arises that shift of the threshold voltage occurs, which is considered to be a cause of weak junction in the silicon film.

In light of the above, a method that uses an SiO film as the gate insulating film can be considered as an approach. In the case of using the SiO film as the gate insulating film, implantation of N into the silicon film as found in the case of using the SiN film does not occur. It is thereby possible to apply laser to the silicon film at an energy density sufficient to crystallize the silicon film. Therefore, it is possible to crystallize the silicon film to the interface with the gate insulating film as shown in FIG. 6, and the shift of the threshold voltage does not occur. Specifically, the polycrystalline silicon film 3 is formed on an SiO film 5 with no amorphous silicon film therebetween.

However, the following problem occurs in this case as well. In consideration of a breakdown voltage and an initial failure rate as the gate insulating film, it is necessary to increase the thickness of the gate insulating film up to about 300 nm or 400 nm. Because an etching rate when processing the SiO film by a known dry etching method is low, it takes a considerable length of time to process the SiO film with such a large thickness, which becomes a factor contributing to degradation of productivity.

As a means of solving the above problems, a method is possible that forms a stacked structure in which a gate insulating film on the side in contact with a silicon film is an SiO film and a gate insulating film on the side in contact with a gate electrode is an SiN film. In such a structure, because the gate insulating film on the side in contact with the silicon film is the SiO film, implantation of N into the silicon film, which is found in the case of using the SiN film as the gate insulating film, does not occur. It is thereby possible to apply laser at an energy density sufficient to crystallize the silicon film, and it is thus possible to crystallize the silicon film to the interface with the gate insulating film. Further, because the gate insulating film on the side in contact with the gate electrode is the SiN film, it is possible to achieve improvement in breakdown voltage and suppression of initial insulating film breakdown by the thickness of the SiN film and therefore the thickness of the SiO film can be reduced, thus offering an advantage that degradation of productivity during processing of the insulating film does not substantially occur.

However, in the so-called etching stopper type TFT which is disclosed in Japanese Unexamined Patent Application Publication No. 2007-5508, a photolithography (mask) process for forming a channel protective film serving as an etching stopper is necessary. Although the time required for such a process is not long with respect to each processing of the insulating film, because one mask process is added, productivity is significantly degraded in an array manufacturing process as a whole.

Therefore, a back-channel-etch type TFT that eliminates the process of forming a channel protective film serving as an etching stopper is preferable in terms of productivity. However, it has been found in our study that the following problem exists in the case of fabricating a back-channel-etch type TFT in which the gate insulating film has a stacked structure of an SiO film and an SiN film as disclosed in Japanese Unexamined Patent Application Publication No. 2001-109014. The back-channel-etch type TFT is fabricated by the following manufacturing method. After forming a gate electrode, a gate insulating film, a semiconductor layer and an ohmic contact layer are sequentially deposited, and the ohmic contact layer and the semiconductor layer are etched by one operation. Next, a metal film is deposited and etched, thereby forming source and drain electrodes. Then, the ohmic contact layer which is formed on a channel is etched away by using the source and drain electrodes as a mask, thereby forming a TFT.

When etching away the ohmic contact layer by dry etching, an exposed part of the gate insulating film is the SiO film. In this case, etching gas (radical) in the ohmic contact layer is not substantially consumed in the SiO film, it is considered to be consumed for etching of the ohmic contact layer. An etching rate of the ohmic contact layer thereby becomes significantly high. Further, because an etching rate depends also on the exposed area ratio between the SiO film and the ohmic contact layer, etching controllability is largely deteriorated. It has been found that a problem arises that it is difficult to control the depth of cutting on the backside of the channel which largely affects TFT characteristics.

The present invention has been accomplished to solve the above problems, and it is desirable to provide aback-channel-etch type thin-film transistor, a semiconductor device and manufacturing methods thereof which enable improvement of productivity and transistor characteristics.

### SUMMARY OF THE INVENTION

A first exemplary aspect of the present invention is a back-channel-etch type thin-film transistor that includes a gate electrode, a silicon nitride film that is formed on the gate electrode, a silicon oxide film that is formed and patterned on the silicon nitride film, and a semiconductor film having crystallinity that is formed and patterned on the silicon oxide film in contact with the silicon oxide film in such a way that all pattern ends of the semiconductor film are located in close proximity to pattern ends of the silicon oxide film.

A second exemplary aspect of the present invention is a method of manufacturing a back-channel-etch type thin-film transistor that includes steps of forming a gate electrode, depositing a silicon nitride film on the gate electrode, depositing a silicon oxide film on the silicon nitride film, depositing an amorphous semiconductor film on the silicon oxide film, and forming a semiconductor film having crystallinity in such a way that all pattern ends of the semiconductor film are located in close proximity to pattern ends of the silicon oxide film by applying laser light to the amorphous semiconductor film and performing patterning.

According to the exemplary aspects of the present invention described above, it is possible to provide a back-channel-etch type thin-film transistor, a semiconductor device and manufacturing methods thereof which enable improvement of productivity and transistor characteristics.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a schematic front view showing a structure of a TFT substrate according to an exemplary embodiment;

FIG. 2 is a schematic cross-sectional view showing a structure of a TFT substrate according to an exemplary embodiment;

FIGS. 3A to 3F are schematic cross-sectional views showing a manufacturing method of a TFT substrate according to an exemplary embodiment;

FIG. 4 is a cross-sectional TEM image showing a structure of an interface between a semiconductor film and a gate insulating film in the case of using an SiN film as the gate insulating film;

FIG. 5 is a graph showing an example of TFT characteristics (linear region) in the case of using an SiN film as a gate insulating film; and

FIG. 6 is a cross-sectional TEM image showing a structure of an interface between a semiconductor film and a gate insulating film in the case of using an SiO film as the gate insulating film.

### DESCRIPTION OF THE EXEMPLARY EMBODIMENTS

### Exemplary Embodiment

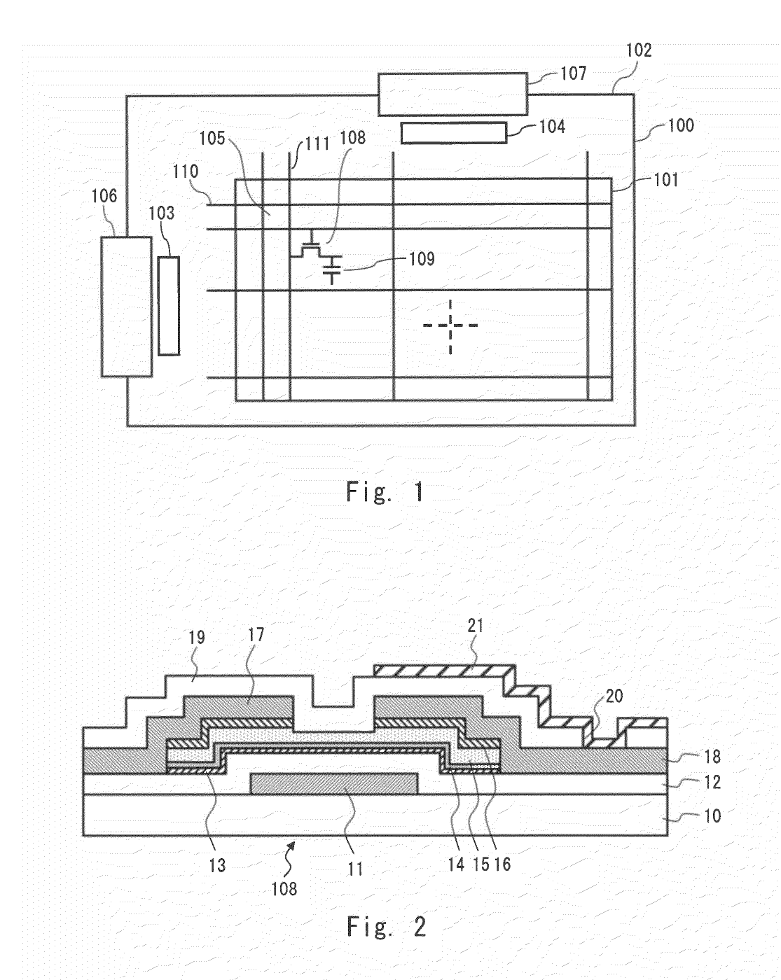

A TFT substrate that includes a thin-film transistor (TFT) according to an exemplary embodiment of the present invention is described firstly with reference to FIG. 1. FIG. 1 is a schematic front view showing a structure of the TFT substrate. The TFT substrate is used for a display (particularly, an active matrix display), which is a semiconductor device. Although a liquid crystal display is described as an example of the display, it is only by way of illustration. Another flat panel display such as an organic EL display may be used as the display as a matter of course.

A liquid crystal display includes a TFT substrate 100. The TFT substrate 100 is a TFT array substrate in which TFTs 108 are arranged in an array, for example. The TFT substrate 100 includes a display area 101 and a frame area 102 surrounding the display area 101. In the display area 101, a plurality of gate lines (scan signal lines) 110, a plurality of capacitor lines (not shown) and a plurality of source lines (display signal lines) 111 are placed.

The plurality of gate lines 110 and the plurality of capacitor lines are placed in parallel. The capacitor lines are respectively placed between the adjacent gate lines 110. Thus, the gate lines 110 and the capacitor lines are arranged alternately with each other. Further, the plurality of source lines 111 are placed in parallel. The gate lines 110 and the source lines 111 are arranged to intersect with each other. The capacitor lines and the source lines 111 are also arranged to intersect with each other. An area surrounded by the adjacent gate lines 110 and the adjacent source lines 111 is a pixel 105. Thus, the capacitor lines are placed to cross the pixels 105. In the TFT substrate 100, the pixels 105 are arranged in matrix.

Further, a scan signal driving circuit 103 and a display signal driving circuit 104 may be placed in the frame area 102 of the TFT substrate 100. The gate lines 110 extend from the display area 101 to the frame area 102. The gate lines 110 are connected to the scan signal driving circuit 103 at the end of the TFT substrate 100. The source lines 111 also extend from the display area 101 to the frame area 102. The source lines 111 are connected to the display signal driving circuit 104 at the end of the TFT substrate 100. An external wiring 106 is connected in close proximity to the scan signal driving circuit 103. Further, an external wiring 107 is connected in close proximity to the display signal driving circuit 104. The external wirings 106 and 107 are wiring boards such as a flexible printed circuit (FPC), for example.

Various kinds of external signals are supplied to the scan signal driving circuit 103 and the display signal driving circuit 104 through the external wirings 106 and 107. The scan signal driving circuit 103 supplies a gate signal (scan signal) to the gate lines 110 according to an external control signal. In response to the gate signal, the gate lines 110 are sequentially selected. The display signal driving circuit 104 supplies a display signal to the source lines 111 according to an external control signal or display data. A display voltage corresponding to the display data can be thereby supplied to the respective pixels 105. The scan signal driving circuit 103 and the display signal driving circuit 104 are not necessarily placed on the TFT substrate 100. For example, driving circuits may be connected by tape carrier package (TCP).

In the pixel 105, at least one TFT 108 and a capacitor 109 that is connected to the TFT 108 are placed. In the pixel 105, the TFT 108 and the capacitor 109 are connected in series. The TFT 108 is placed in close proximity to an intersection between the source line 111 and the gate line 110. The TFT 108 serves as a switching device for supplying a display voltage to a pixel electrode, for example. A gate electrode of the TFT 108 is connected to the gate line 110, and ON and OFF of the TFT 108 are controlled according to a gate signal that is input through the gate terminal. If a voltage is applied to the gate electrode and the TFT 108 is turned ON, a current flows from the source line 111. A display voltage is thereby applied to the pixel electrode that is connected to a drain electrode of the TFT 108. Then, an electric field corresponding to the display voltage is generated between the pixel electrode and a counter electrode.

On the other hand, the capacitor 109 is electrically connected also to the counter electrode through the capacitor line, not only to the TFT 108. Thus, the capacitor 109 is connected in parallel to a capacitor between the pixel electrode and the counter electrode. The capacitor 109 can hold a voltage applied to the pixel electrode for a given length of time. An alignment layer (not shown) is placed on the surface of the TFT substrate 100. The TFT substrate 100 has the above-described structure.

Further, in the case of the liquid crystal display, a counter substrate is placed opposite to the TFT substrate 100. The counter substrate is a color filter substrate, for example, and placed on the viewing side. In the counter substrate, a color filter, a black matrix (BM), a counter electrode, an alignment layer and so on are placed. In the case of an IPS liquid crystal display, for example, the counter electrode is placed on the TFT substrate 100 side. Further, a liquid crystal layer is placed between the TFT substrate 100 and the counter substrate. In other words, liquid crystals are filled between the TFT substrate 100 and the counter substrate. Furthermore, a polarizing plate, a retardation film and so on are placed on the respective outer sides of the TFT substrate 100 and the counter substrate. In addition, a backlight unit or the like is placed on the non-viewing side of the liquid crystal display panel having the above structure.

The liquid crystals are driven by the electric field between the pixel electrode and the counter electrode. Specifically, the orientation of the liquid crystals between the substrates is changed. The polarization state of light passing through the liquid crystal layer is thereby changed. Specifically, the polarization state of light that has been linearly polarized through the polarizing plate is changed by the liquid crystal layer. To be more precise, light from the backlight unit and outside light that is incident from outside are linearly polarized by the polarizing plate on the TFT substrate 100 side. The linearly polarized light then passes through the liquid crystal layer, thereby changing its polarization state.

Accordingly, the amount of light passing through the polarizing plate on the counter substrate side varies depending on the polarization state. Specifically, the amount of light passing through the polarizing plate on the viewing side, among transmitted light that is transmitted through the liquid crystal display panel from the backlight unit, varies. The orientation of the liquid crystals varies depending on a display voltage to be applied. Thus, the amount of light passing through the polarizing plate on the viewing side can be changed by controlling the display voltage. Specifically, a desired image can be displayed by varying the display voltage for each pixel. Further, as the area of devices formed on the TFT substrate 100 is smaller, the larger amount of light from the backlight unit can be transmitted. This achieves high luminance and enables reduction of the light intensity of the backlight unit, which leads to reduction of power consumption. In the series of operations, an electric field is generated in parallel with the electric field between the pixel electrode and the counter electrode in the capacitor 109, which contributes to maintaining the display voltage.

Referring next to FIG. 2, the structure of the TFT 108 for pixel switching which is placed in the TFT substrate 100 is described hereinbelow. FIG. 2 is a schematic cross-sectional view showing the structure of the TFT substrate 100 in the part where the TFT 108 for pixel switching is formed. The TFT 108 according to the exemplary embodiment is a back-channel-etch type TFT of an inversely staggered type.

A gate electrode 11 is formed on an insulating substrate 10. A glass substrate, for example, is used as the insulating substrate 10. Then, a gate insulating film is formed to cover the gate electrode 11. In this exemplary embodiment, the gate insulating film includes a silicon nitride (SiN) film 12 and a silicon oxide (SiO) film 13 in this sequence from the gate electrode 11 side. The SiN film 12 is formed substantially all over the insulating substrate 10. The SiN film 12 is formed to protrude from the SiO film 13. The SiO film 13 is formed on the SiN film 12 in the position opposite to the gate electrode 11. The SiO film 13 is formed to protrude from the gate electrode 11. The thickness of the SiO film 13 is smaller than the thickness of the SiN film 12.

On the SiO film 13, a polycrystalline semiconductor film 14 which serves as a semiconductor film having crystallinity is formed. In other words, the SiO film 13 is formed between the polycrystalline semiconductor film 14 and the SiN film 12. Further, the SiO film 13 is in direct contact with the SiN film 12 and the polycrystalline semiconductor film 14. The polycrystalline semiconductor film 14 is formed in such a way that all pattern ends are located in close proximity to pattern ends of the SiO film 13. In other words, the pattern ends of the polycrystalline semiconductor film 14 are located in close proximity to all pattern ends of the SiO film 13. Further, the polycrystalline semiconductor film 14 is preferably formed to be inclusive of the pattern of the SiO film 13. In other words, the SiO film 13 is preferably formed not to protrude from the polycrystalline semiconductor film 14. In this exemplary embodiment, the polycrystalline semiconductor film 14 has substantially the same planar size as the SiO film 13. Thus, the polycrystalline semiconductor film 14 substantially coincides with the SiO film 13 when viewed from above. A polycrystalline silicon film, for example, is used as the polycrystalline semiconductor film 14.

An amorphous semiconductor film 15 is formed on the polycrystalline semiconductor film 14. The amorphous semiconductor film 15 has substantially the same planar size as the polycrystalline semiconductor film 14. An ohmic contact layer 16 is formed on the amorphous semiconductor film 15. An intrinsic amorphous silicon film, for example, is used as the amorphous semiconductor film 15. The ohmic contact layer 16 is a semiconductor film that contains an impurity element and has conductivity. An amorphous silicon film that contains phosphorus as an impurity element, for example, may be used as the ohmic contact layer 16. Further, the ohmic contact layer 16 is not formed in the center part above the gate electrode 11. The part of the amorphous semiconductor film 15 on which the ohmic contact layer 16 is not formed is a channel region. In the channel region, the thickness of the amorphous semiconductor film 15 is smaller.

In FIG. 2, the ohmic contact layer 16 is formed at each of both ends above the gate electrode 11. One ohmic contact layer 16 forms a source region, and the other ohmic contact layer 16 forms a drain region. Thus, the source region and the drain region are placed opposite to each other with the channel region interposed therebetween. The channel region is a region in which a channel is formed when a gate voltage is applied to the gate electrode 11. Specifically, when a gate voltage is applied to the gate electrode 11, a channel is formed on the backside of the channel region. Then, when a gate voltage is applied in the state where a given voltage is supplied between the source region and the drain region, a drain current flows between the source region and the drain region.

In the source region, a source electrode 17 is formed on the ohmic contact layer 16. The source region and the source electrode 17 are in contact with each other. The source electrode 17 may be formed integrally with the source line 111. A voltage is supplied to the source region through the source electrode 17. In the drain region, a drain electrode 18 is formed on the ohmic contact layer 16. The drain region and the drain electrode 18 are in contact with each other. Further, the source electrode 17 and the drain electrode 18 are formed to protrude from the semiconductor layer including the polycrystalline semiconductor film 14, the amorphous semiconductor film 15 and the ohmic contact layer 16 so that they are in contact with the SiN film 12. The TFT 108 has the above-described structure.

Further, an interlayer insulating film 19 is formed above the SiN film 12 so as to cover the source electrode 17 and the drain electrode 18. The interlayer insulating film 19 has a contact hole 20 above the drain electrode 18. A pixel electrode 21 is formed on the interlayer insulating film 19. Further, the pixel electrode 21 is buried in the contact hole 20. The pixel electrode 21 and the drain electrode 18 are thereby electrically connected. Display is performed by applying a voltage to liquid crystals or an electrooptic material such as a selfluminous element by the pixel electrode 21, although not shown.

The TFT 108 according to the exemplary embodiment has a high mobility and good reliability because the part where the channel of the semiconductor film is formed has crystallinity. Further, the SiO film 13 and the polycrystalline semiconductor film 14 are in direct contact with each other. Thus, the semiconductor film has crystallinity at the interface with the gate insulating film. It is thereby possible to suppress increase in S value and degradation of mobility. Further, the shift of a threshold voltage, which is considered to be a cause of weak junction, does not easily occur. As described above, it is possible to improve TFT characteristics according to the exemplary embodiment.

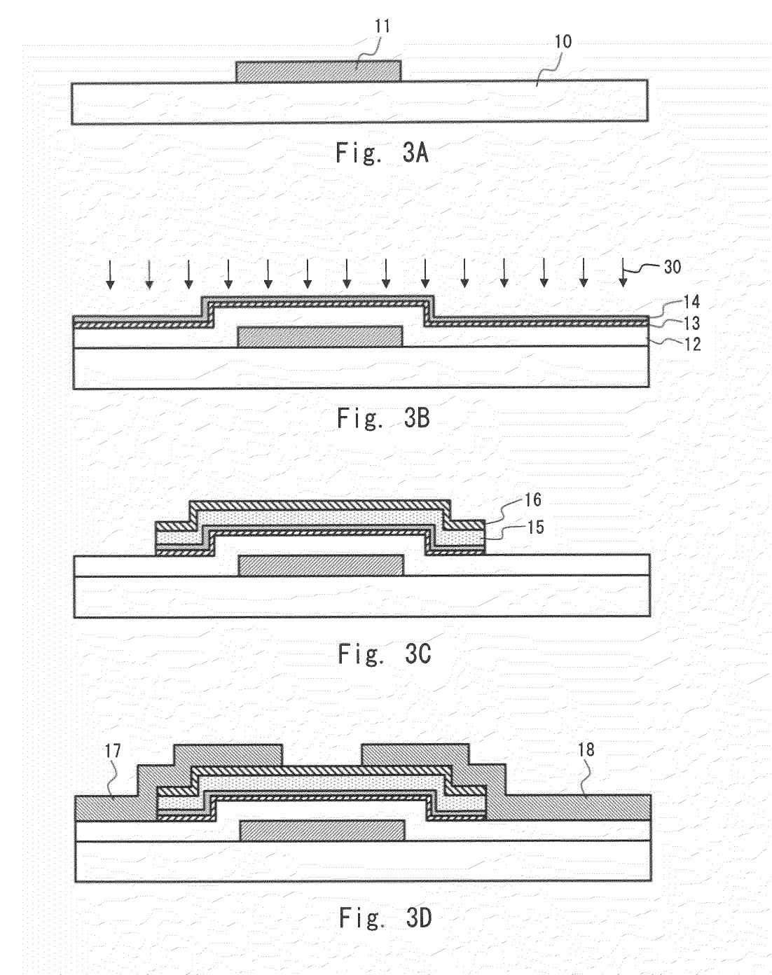

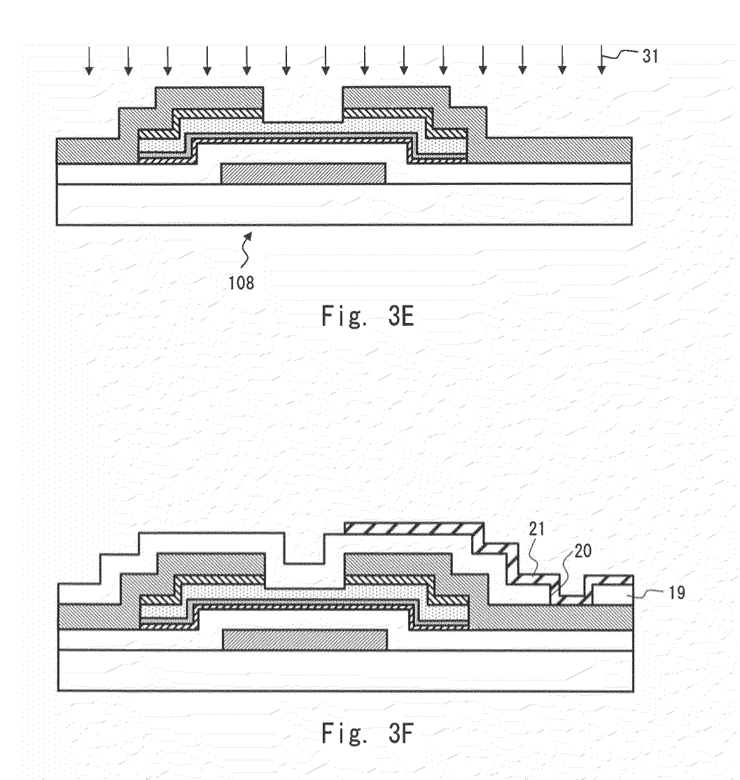

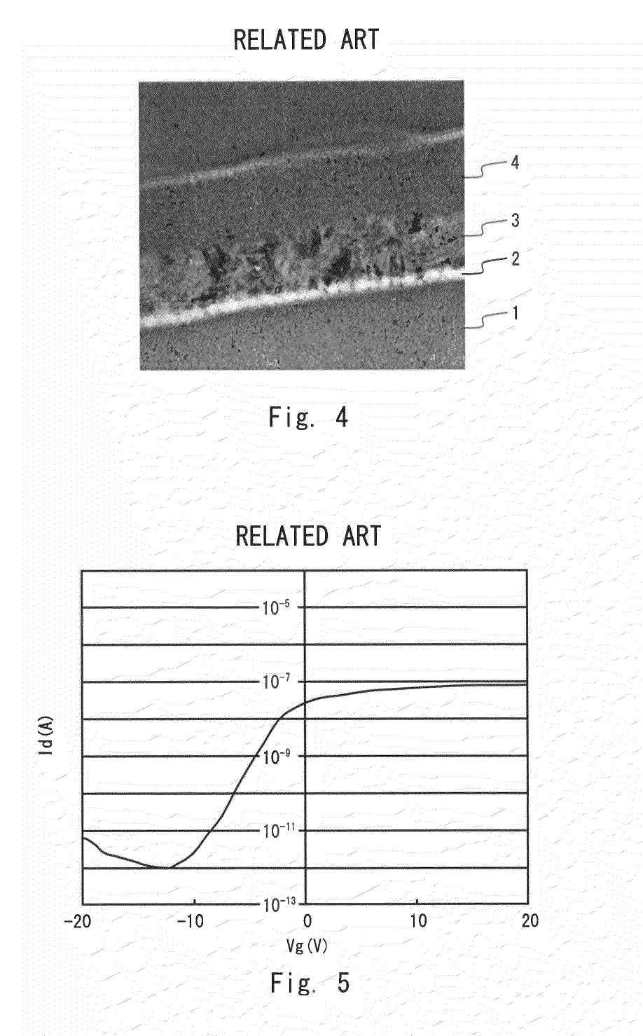

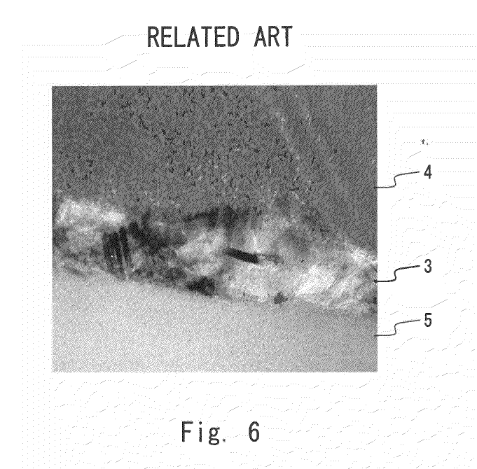

A method of manufacturing the TFT 108 according to the exemplary embodiment is described hereinafter with reference to FIGS. 3A to 3F. FIGS. 3A to 3F are schematic cross-sectional views showing a manufacturing method of the TFT substrate 100 that includes the TFT 108.

First, a metal film is deposited by DC-magnetron sputtering on the insulating substrate 10 having light transmitting properties such as a glass substrate or a quartz substrate. In this exemplary embodiment, a non-alkali glass substrate is used as the insulating substrate 10. Further, a metal film (alloy film) that is predominantly composed of aluminum is used as the metal film. In this exemplary embodiment, an alloy film in which a given amount of nickel and neodymium are added to aluminum is used as the metal film. Heat resisting properties are thereby improved, thus reducing damage such as deformation due to laser light which is applied later. The alloy film is deposited with a thickness of approximately 200 nm.

Then, hitherto-known photolithography that coats photoresist which is photosensitive resin on the metal film by spin coating and then performs exposure and development of the coated resist is conducted. The photoresist is thereby patterned into a desired shape. After that, the metal film is wet-etched by using the photoresist as a mask and patterned into a desired shape. The photoresist pattern is then removed. The gate electrode 11 is thereby formed. In this exemplary embodiment, a drug solution containing phosphoric acid as the main ingredient is used as etchant of wet etching. The end face of the gate electrode 11 preferably has a tapered shape. With the tapered shape, covering properties of the SiN film 12 which is deposited later is improved. This offers an advantage of improving a breakdown voltage. By the above process, the structure shown in FIG. 3A is constructed.

Next, a gate insulating film is deposited on the gate electrode 11 by plasma CVD. Specifically, a stacked layer of the SiN film 12 and the SiO film 13 is formed on the gate electrode 11. In this exemplary embodiment, the SiN film 12 is deposited with a thickness of approximately 350 nm on the gate electrode 11. Then, the SiO film 13 is formed with a thickness of approximately 50 nm on the SiN film 12. The thicknesses of the SiN film 12 and the SiO film 13 are not limited to those thicknesses, and they may be determined in consideration of a breakdown voltage, insulating film capacitance, productivity and so on. In this example, as the insulating film, the SiN film 12 which has a relatively high etching rate by dry etching and has good processability is formed to be thick, thereby securing a breakdown voltage. Further, the SiO film 13 which has a low dry etching rate is formed to be thin, thereby preventing degradation of productivity.

Then, an amorphous semiconductor film is deposited on the gate insulating film by plasma CVD. Specifically, the amorphous semiconductor film is deposited on the SiO film 13. In this exemplary embodiment, an amorphous silicon (a-Si) film is used as the amorphous semiconductor film. The a-Si film is deposited with a thickness of approximately 40 nm.

Further, the SiO film 13 is placed between the amorphous semiconductor film and the gate insulating film, so that the amorphous semiconductor film and the SiN film 12 are not in contact with each other. Therefore, when applying laser light to the amorphous semiconductor film for crystallization in the subsequent process, implantation of N in the insulating film into the semiconductor film or the like does not occur. It is thereby possible to apply laser at an energy density which is necessary to crystallize the amorphous semiconductor film. Therefore, it is possible to crystallize the semiconductor film to the interface with the gate insulating film. Further, because a layer in which amorphous substance and crystalline substance are mixed is not formed on the interface between the gate insulating film and the semiconductor film, it is possible to suppress the shift of a threshold voltage due to fixed charges.

The amorphous semiconductor film which is deposited by plasma CVD as in this exemplary embodiment abundantly contains hydrogen. It is therefore preferred to carry out annealing at high temperature as processing for reducing the hydrogen. In this exemplary embodiment, a chamber which is maintained in a low vacuum state in a nitrogen atmosphere is heated to 400° C., and the substrate on which the amorphous semiconductor film is deposited is held for 30 minutes. As a result of such processing, it is possible to suppress roughness of the semiconductor film surface due to sudden desorption of hydrogen with a temperature increase when crystallizing the amorphous film.

Then, inert gas such as nitrogen is sprayed on the amorphous semiconductor film, thereby reducing the oxygen concentration on the surface of the amorphous semiconductor film. In this state, laser light 30 is applied to the amorphous semiconductor film. The laser light 30 is applied to the amorphous semiconductor film after it is shaped into a linear beam shape through a prescribed optical system. The amorphous semiconductor film is thereby molten once and transformed into a semiconductor film having crystallinity (the polycrystalline semiconductor film 14). In this exemplary embodiment, excimer laser (with an oscillation wavelength of 308 nm) is used as the laser light 30. Further, a beam shape is a linear beam shape with approximately 400 μm×200 mm, and an irradiation energy density is 250 mJ/cm². Then, the amorphous semiconductor thin film is scanned perpendicularly to the longitudinal direction of the linear beam at a feed pitch of 30 μm.

As a result of applying the laser light 30 to the semiconductor film a plurality of times at such an irradiation energy, the semiconductor film can be crystallized to the interface with the SiO film 13. Specifically, the polycrystalline semiconductor film 14 is formed in contact with the SiO film 13 with no amorphous semiconductor film or the like interposed therebetween. Although the irradiation energy density is set to 250 mJ/cm² in this example, it is preferably in the range of 200 mJ/cm² to 350 mJ/cm². If the irradiation energy density is lower than 200 mJ/cm², the semiconductor film is not sufficiently crystallized, causing increase in S value and degradation of mobility. On the other hand, if the irradiation energy density is higher than 350 mJ/cm², surface roughness of the semiconductor film, degradation of crystallinity, damage to the gate electrode film or the like occurs, which is not preferable. In the above process, the SiN film 12, the SiO film 13 and the polycrystalline semiconductor film 14 are sequentially formed on the gate electrode 11, so that the structure shown in FIG. 3B is constructed.

Then, the substrate is cleaned with a drug solution of hydrofluoric acid or the like in order to remove a native oxide film on the surface of the polycrystalline semiconductor film 14. After that, the amorphous semiconductor film 15 and the ohmic contact layer 16 are sequentially deposited by plasma CVD. In this exemplary embodiment, an intrinsic amorphous silicon (i-a-Si) film is used as the amorphous semiconductor film 15. The i-a-Si film is deposited with a thickness of approximately 150 nm. Further, an amorphous silicon (n⁺a-Si) film that contains phosphorus as an impurity element is used as the ohmic contact layer 16. The n⁺a-Si film is deposited with a thickness of approximately 30 nm.

Then, the ohmic contact layer 16, the amorphous semiconductor film 15, the polycrystalline semiconductor film 14 and the SiO film 13 are patterned into a desired shape by using known photolithography and dry etching. The surface of the SiN film 12 is thereby exposed as shown in FIG. 3C. In this exemplary embodiment, mixed gas of CF₄ and O₂ is used as etching gas. Etching is thereby performed with recession of the photoresist, so that pattern ends of the ohmic contact layer 16, the amorphous semiconductor film 15, the polycrystalline semiconductor film 14 and the SiO film 13 have tapered shapes. Specifically, by the patterning, the polycrystalline semiconductor film 14 is formed in such a way that all pattern ends of the polycrystalline semiconductor film 14 are located in close proximity to the pattern ends of the SiO film 13. For example, the polycrystalline semiconductor film 14 is formed in such a way that the bottom surface of the polycrystalline semiconductor film 14 and the top surface of the SiO film 13 coincide with each other as in this exemplary embodiment. In other words, the bottom surface of the polycrystalline semiconductor film 14 is formed to be inclusive of the pattern of the top surface of the SiO film 13.

Further, as a result that the ohmic contact layer 16, the amorphous semiconductor film 15, the polycrystalline semiconductor film 14 and the SiO film 13 are tapered as described above, the covering properties of the metal film which is deposited later is improved. This offers an advantage of suppressing a break due to a step at the patterns of the above semiconductor film and the SiO film 13. Further, because the SiO film 13 is formed to be as thin as 50 nm, the etching time does not largely increase, which suppresses degradation of productivity.

Then, a metal film for forming the source electrode 17 and the drain electrode 18 is deposited on the ohmic contact layer 16 by DC-magnetron sputtering. In this exemplary embodiment, a Cr film is used as the metal film. The Cr film is deposited with a thickness of approximately 200 nm. After that, the metal film is processed into a desired pattern by known photolithography and wet etching. The source electrode 17 and the drain electrode 18 are thereby formed. As an etchant to be used for wet etching, a drug solution containing perchloric acid and cerium ammonium nitrate is used. By the above process, the structure shown in FIG. 3D is constructed.

Then, the ohmic contact layer 16 which is placed between the source electrode 17 and the drain electrode 18 is etched by dry etching. Specifically, the ohmic contact layer 16 is etched by using the source electrode 17 and the drain electrode 18 as a mask. The ohmic contact layer 16 and a part of the amorphous semiconductor film 15 in the thickness direction are thereby removed above the gate electrode 11. In this exemplary embodiment, the total film thickness to be etched in the ohmic contact layer 16 and the amorphous semiconductor film 15 by over-etching is approximately 80 nm. Because the ohmic contact layer 16 is deposited with a thickness of 30 nm, the depth of etching of the amorphous semiconductor film 15 is approximately 50 nm.

Consequently, the ohmic contact layer 16 is completely divided into a source region and a drain region with a channel region interposed therebetween. In the case of performing etching of the ohmic contact layer 16 in the state where the SIC film 13 is exposed, etching gas (radical) 31 is not largely consumed in the SiO film 13 and used for etching of the ohmic contact layer 16. It has been found in our study that an etching rate of the ohmic contact layer 16 thereby becomes significantly higher. Therefore, it is difficult to etch the ohmic contact layer 16 with good controllability in the state where the SiO film 13 is exposed, and it is thus difficult to stabilize the amount of the remaining film of the semiconductor film in the channel region, which causes fluctuation in TFT characteristics.

According to the exemplary embodiment of the present invention, the SiO film 13, which is the gate insulating film on the side in contact with the semiconductor film, is processed at the same time as etching the semiconductor film, in the state where the SiN film 12 is exposed. Thus, in the etching process, the surface of the SiO film 13 is substantially completely covered with the semiconductor film or the like. It is thereby possible to suppress an increase in the etching rate of the ohmic contact layer 16, which enables etching of the ohmic contact layer 16 with good controllability. An advantage of stabilizing TFT characteristics is thereby obtained. Further, because the source electrode 17 and the drain electrode 18 are used as a mask when dividing the ohmic contact layer 16 into a source region and a drain region, photolithography process is not increased, thus allowing simplification of the production process. It is thereby possible to reduce the material such as resist to be consumed in the photolithography process. By the above process, the structure shown in FIG. 3E is constructed, so that the TFT substrate 100 is formed.

After that, the interlayer insulating film 19 is deposited to cover the source electrode 17 and the drain electrode 18 by plasma CVD. As the interlayer insulating film 19, an SiN film, an SiO film or a stacked layer of those films is used. In this exemplary embodiment, the SiN film is used as the interlayer insulating film 19. The SiN film is deposited with a thickness of approximately 300 nm. Then, the interlayer insulating film 19 is processed into a desired pattern by known photolithography and dry etching. The interlayer insulating film 19 on the drain electrode 18 is thereby removed to make the contact hole 20. Thus, the drain electrode 18 is exposed in the contact hole 20.

Further, although not shown, the contact hole 20 in which the interlayer insulating film 19 is removed is made also above the gate line 110 in the area outside the display area 101. In the contact hole 20 which is made above the gate line 110, the SiN film 12 is removed in addition to the interlayer insulating film 19, and the surface of the gate line 110 is exposed. Although it is usually necessary to remove the SiO film 13 which constitutes the gate insulating film that is formed once on the gate line 110 when making the contact holes 20, the SiO film 13 is etched at the same time as the semiconductor film and thus removed except for the part where the semiconductor film is formed in this exemplary embodiment. Therefore, the interlayer insulating film 19 made of SiN and the SiN film 12 are etched during dry etching for making the contact hole 20, and it is thus possible to make the contact hole 20 stably without need for etching of the SiO film 13, which a different material, during the dry etching process.

Then, a conductive film having transparency such as ITO or IZO is deposited on the interlayer insulating film 19 in order to form the pixel electrode 21. In this exemplary embodiment, an amorphous transparent conductive film with good processability is deposited by sputtering using DC magnetron. In this example, mixed gas of Ar gas, O₂ gas and H₂O gas is used. Then, the conductive film is patterned into a desired shape by known photolithography, thereby forming the pixel electrode 21. The pixel electrode 21 is patterned so as to come into contact with the drain electrode 18 through the contact hole 20. Further, in the area outside the display area 101, a connection pattern that establishes connection between the gate line 110 and the scan signal driving circuit 103 or the like through the contact hole 20 made on the gate line 110 is formed by patterning the conductive film having transparency, at the same time as forming the pixel electrode 21. In this exemplary embodiment, the conductive film is etched by wet etching using a drug solution containing oxalic acid as the main ingredient. In the case of using an ITO film as the conductive film, annealing at a temperature of approximately 300° C. may be performed for crystallization. The TFT substrate 100 is thereby completed as shown in FIG. 3F.

In this exemplary embodiment, because the gate insulating film on the side in contact with the semiconductor film is the SiO film 13, it is possible to crystallize the semiconductor film to the interface with the gate insulating film as described above. It is thereby possible to suppress the shift of a threshold voltage. Further, because the part of the semiconductor film where the channel is formed has crystallinity, it is possible to form the TFT 108 having a high mobility and good reliability compared to the case where it is the amorphous semiconductor film. It is thus possible to form the TFT 108 with high driving capacity.

Further, the gate insulating film on the side in contact with the gate electrode 11 is the SiN film 12, and it is possible to secure a breakdown voltage and suppress initial insulating film breakdown by adjusting the thickness of the SiN film 12. Further, by forming the SiN film 12, it is possible to allow the SiO film 13 with a low dry etching rate to be thin. Accordingly, degradation of productivity during processing of the insulating film does not substantially occur. It is thus possible to improve both TFT characteristics and productivity.

Furthermore, because the TFT has a back-channel-etch type structure, it is possible to simplify an array manufacturing process, thus further improving productivity. This achieves resource saving. In addition, processing of etching away the back channel part that includes the ohmic contact layer 16 formed on the backside of the channel by using the source electrode 17 and the drain electrode 18 as a mask is performed in the state where the gate insulating film is exposed. Because the exposed gate insulating film surface is the SiN film 12, an increase in the etching rate of the back channel, which is found in the case of the SiO film 13, does not occur, and it is thus possible to perform etching of the back channel with good controllability. This enables stabilization of TFT characteristics. Therefore, process stability is improved in a method of manufacturing the TFT 108 according to the exemplary embodiment. Although the back-channel-etch type TFT is used in this example, the present invention may be applied to an etching stopper type TFT. Further, although the polycrystalline semiconductor film is used as an example of the semiconductor film having crystallinity, a microcrystalline semiconductor film may be used instead.

Further, a driving circuit for which device driving capacity and reliability are required can be formed on the same substrate, so that it is possible to reduce costs by reducing the number of external ICs and thereby obtain a semiconductor device that achieves resource saving with the reduced number of external ICs.

In this exemplary embodiment, because the SiO film 13 and the polycrystalline semiconductor film 14 are formed to have substantially the same planar size, it is possible to achieve both stable cutting of the back channel part and improvement of productivity due to that the semiconductor film such as the polycrystalline semiconductor film 14 and the SiO film 13 are processable with one mask. The polycrystalline semiconductor film 14 and the SiO film 13 do not necessarily have substantially the same planar size as a matter of course, and the SiO film 13 may be formed to be smaller so that the SiO film 13 is covered with the polycrystalline semiconductor film 14, for example. In this case, after depositing the SiO film 13, the SiO film 13 is patterned, for example. Then, the amorphous semiconductor film is deposited on the SiO film 13, and the amorphous semiconductor film is transformed into the polycrystalline semiconductor film 14 as shown in FIG. 3B. After that, the polycrystalline semiconductor film 14 is patterned to protrude from the SiO film 13.

Further, the polycrystalline semiconductor film 14 is not necessarily formed to be inclusive of the pattern of the SiO film 13 as described above, as long as all pattern ends of the polycrystalline semiconductor film 14 are located in close proximity to the pattern ends of the SiO film 13. On the contrary, the pattern of the SiO film 13 may be somewhat larger than the polycrystalline semiconductor film 14. In other words, the pattern of the SiO film 13 may be formed to protrude from the pattern of the polycrystalline semiconductor film 14. In this case also, because the surface of the SiO film 13 is not substantially exposed if the SiO film 13 is removed in a large part of area excluding the part below the polycrystalline semiconductor film 14, it is possible to suppress an increase in the etching rate of the ohmic contact layer 16. Consequently, it is possible to perform etching of the ohmic contact layer 16 with good controllability, thus enabling stabilization of TFT characteristics.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A back-channel-etch type thin-film transistor comprising:
a gate electrode;
a silicon nitride film that is formed on the gate electrode;
a silicon oxide film that is formed and patterned on the silicon nitride film; and
a semiconductor film having crystallinity that is formed and patterned on the silicon oxide film in contact with the silicon oxide film in such a way that all pattern ends of the semiconductor film are located in close proximity to pattern ends of the silicon oxide film.

2. The back-channel-etch type thin-film transistor according to claim 1, further comprising:
an amorphous semiconductor film that is formed on the semiconductor film having crystallinity.

3. The back-channel-etch type thin-film transistor according to claim 1, wherein the semiconductor film having crystallinity and the silicon oxide film have substantially the same planar size.

4. The back-channel-etch type thin-film transistor according to claim 1, wherein the silicon oxide film is smaller than the semiconductor film having crystallinity and covered with the semiconductor film having crystallinity.

5. The back-channel-etch type thin-film transistor according to claim 1, wherein a thickness of the silicon oxide film is smaller than a thickness of the silicon nitride film.

6. A semiconductor device comprising the back-channel-etch type thin-film transistor according to claim 1.

7. A method of manufacturing a back-channel-etch type thin-film transistor comprising steps of:
forming a gate electrode;
depositing a silicon nitride film on the gate electrode;
depositing a silicon oxide film on the silicon nitride film;
depositing an amorphous semiconductor film on the silicon oxide film; and
forming a semiconductor film having crystallinity in such a way that all pattern ends of the semiconductor film are located in close proximity to pattern ends of the silicon oxide film by applying laser light to the amorphous semiconductor film and performing patterning.

8. The method of manufacturing a back-channel-etch type thin-film transistor according to claim 7, wherein in applying laser light, excimer laser with an oscillation wavelength of 308 nm is applied as the laser light.

9. The method of manufacturing a back-channel-etch type thin-film transistor according to claim 8, wherein an irradiation energy density of the excimer laser is in a range of 200 mJ/cm² to 350 mJ/cm².

10. The method of manufacturing a back-channel-etch type thin-film transistor according to claim 7, wherein in the step of forming a semiconductor film, the semiconductor film having crystallinity is formed in such a way that all pattern ends of the semiconductor film are located in close proximity to pattern ends of the silicon oxide film by applying laser light to the amorphous semiconductor film for transformation into the semiconductor film having crystallinity and then patterning the semiconductor film having crystallinity and the silicon oxide film.

11. A method of manufacturing a semiconductor device comprising the method of manufacturing a back-channel-etch type thin-film transistor according to claim 7.
